(19) United States
(12) Patent Application Publication
(10) Pub. No.: US 2026/0215231 A1
(43) Pub. Date: Jul. 23, 2026

(54) MEMORY INTEGRATED CIRCUIT AND MANUFACTURING METHOD THEREOF

(71) Applicant: Winbond Electronics Corp., Taichung City (TW)

(72) Inventor: Ya-Ying Tsai, Tainan (TW)

(73) Assignee: Winbond Electronics Corp., Taichung City (TW)

(21) Appl. No.: 19/419,088

(22) Filed: Dec. 14, 2025

(30) Foreign Application Priority Data
Jan. 20, 2025 (TW) 114102249

(51) Int. Cl. H10P 74/00; H10B 12/00

(52) U.S. Cl. CPC H10P 74/273; H10B 12/30

(57) ABSTRACT

A memory integrated circuit and a manufacturing method thereof are provided. The memory integrated circuit includes memory arrays in chip regions of a semiconductor wafer; and test structures in a scribe line region of the semiconductor wafer. The memory arrays and the test structures respectively include word lines and insulating structures extending along the same direction. The insulating structures in each memory array are configured to define locations of capacitor contact structures. The insulating structures in each memory array are arranged with a first pitch, and the insulating structures in each test structure are arranged with a second pitch greater than the first pitch.

### CROSS-REFERENCE TO RELATED APPLICATION

This application claims the priority benefit of Taiwan application serial no. 114102249, filed on Jan. 20, 2025. The entirety of the above-mentioned patent application is hereby incorporated by reference herein and made a part of this specification.

### BACKGROUND

### Technical Field

The disclosure relates to an integrated circuit and a manufacturing method thereof, and in particular relates to a memory integrated circuit and a manufacturing method thereof.

### Description of Related Art

Dynamic random access memory (DRAM), a type of semiconductor memory, is frequently employed as the main memory in memory systems due to its advantages of high storage density and rapid operational speed. To further increase storage density, DRAM cells are continuously miniaturized. However, the limitation of lithography process leads to many side effects during the miniaturization of DRAM cells, such as alignment issues between patterns. While further improving lithography technology, a verification mechanism must also be designed to ensure the reliability of DRAM.

### SUMMARY

A memory integrated circuit is provided in one aspect of the disclosure, including multiple memory arrays located in multiple chip regions of a semiconductor wafer; and multiple test structures located in a scribe line region of the semiconductor wafer. The memory arrays and the test structures respectively include multiple word lines and multiple insulating structures extending along a same direction. The insulating structures in each of the memory arrays are configured to define multiple capacitor contact structures. The insulating structures in each of the memory arrays are arranged with a first pitch, and the insulating structures in each of the test structures are arranged with a second pitch greater than the first pitch.

A memory integrated circuit is provided in another aspect of the disclosure, including multiple functional pattern arrays located in multiple chip regions of a semiconductor wafer; and multiple test structures located in a scribe line region of the semiconductor wafer. The functional pattern arrays and the test structures respectively include multiple first patterns and multiple second patterns extending along a same direction. The second patterns in each of the functional pattern arrays are configured to define locations of multiple third patterns. The second patterns in each of the functional pattern arrays are arranged with a first pitch, and the second patterns in each of the test structures are arranged with a second pitch greater than the first pitch.

A manufacturing method of a memory integrated circuit is provided in yet another aspect of the disclosure, including forming multiple memory arrays in multiple chip regions of a semiconductor wafer; and forming multiple test structures in a scribe line region of the semiconductor wafer. The memory arrays and the test structures respectively include multiple word lines and multiple insulating structures extending along a same direction. The insulating structures in each of the memory arrays are configured to define multiple capacitor contact structures. The insulating structures in each of the memory arrays are arranged with a first pitch, and the insulating structures in each of the test structures are arranged with a second pitch greater than the first pitch.

### BRIEF DESCRIPTION OF THE DRAWINGS

FIG. 1A and FIG. 1B are schematic plan views of an intermediate structure of a memory integrated circuit during a manufacturing process according to some embodiments of the disclosure.

FIG. 2A to FIG. 2F are cross-sectional schematic diagrams of a series of intermediate structures during a self-aligned double patterning process for forming a capacitor contact structure according to some embodiments of the disclosure.

FIG. 3A is a cross-sectional schematic diagram of an intermediate structure at a stage of forming a first insulating structure for defining a capacitor contact structure according to some embodiments of the disclosure.

FIG. 3B is a schematic plan view of the test structure shown in FIG. 3A when a word line undergoes pitch walking.

FIG. 4A to FIG. 4D are cross-sectional schematic diagrams of a series of intermediate structures during a self-aligned reverse patterning process for forming a capacitor contact structure according to some embodiments of the disclosure.

FIG. 5 is a cross-sectional schematic diagram of an intermediate structure at a stage of forming a second insulating structure for defining a capacitor contact structure according to some embodiments of the disclosure.

### DETAILED DESCRIPTION OF DISCLOSED EMBODIMENTS

The memory integrated circuit of the disclosure will be described below using a DRAM integrated circuit. However, after understanding the lithography verification mechanism disclosed herein, it should be understood that the lithography verification mechanism may also be applied to other memory integrated circuits or any integrated circuit with a periodic pattern.

The DRAM integrated circuit includes multiple memory cells arranged in an array, each of which includes an access transistor and a storage capacitor coupled to the access transistor. In terms of process sequence, an access transistor may be formed in a semiconductor wafer first, and then a storage capacitor may be formed on the semiconductor wafer. In addition, after forming the access transistor and before forming the storage capacitor, various components including a bit line contact structure, a bit line, and a capacitor contact structure, etc. may be formed on the semiconductor wafer.

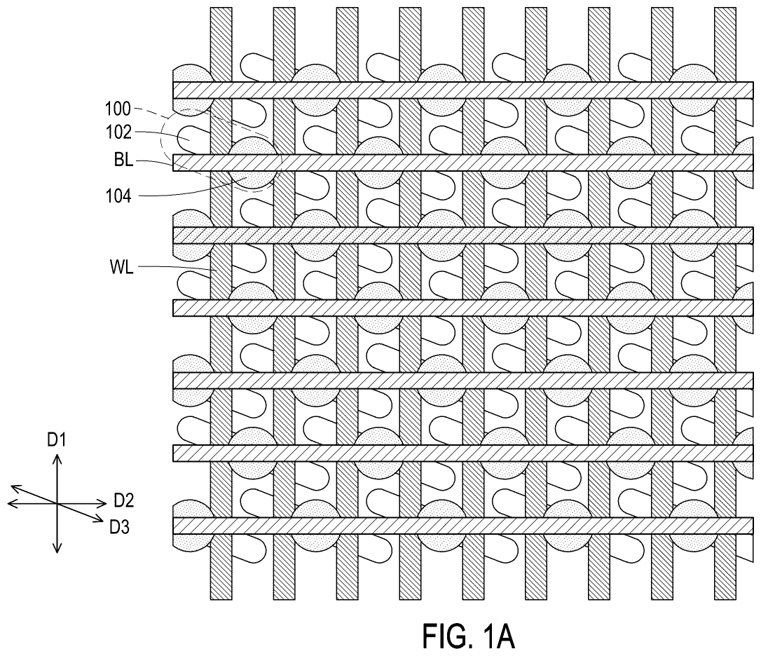

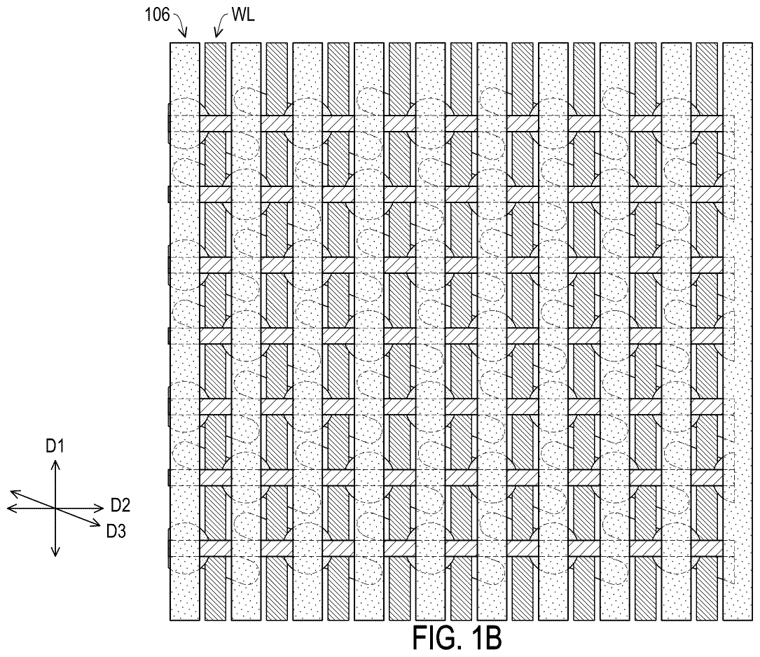

In the intermediate stage shown in FIG. 1A, the access transistor 100 has been formed in the semiconductor substrate. Specifically, each access transistor 100 is defined at the intersection of an active region 102 and a word line WL. The word line WL serves as a gate of the access transistor 100, and portions of the active region 102 located on the two sides of the word line WL serve as a drain and a source of the access transistor.

Each active region 102 is shared by two access transistors 100. In these embodiments, each active region 102 intersects two word lines WL. The defined two access transistors 100 utilize the portion of the active region 102 located between the two word lines WL as a common drain/source.

The word lines WL extend along a direction D1 and are arranged along a direction D2 perpendicular to the direction D1. On the other hand, the active region 102 may extend along a direction D3 that intersects the direction D1 and the direction D2 and be arranged in an array. The active regions 102 in each column are arranged along a direction D1, and the active regions 102 in each row are arranged along a direction D2. In some embodiments, each row of active regions 102 is displaced in a direction D2 relative to two adjacent rows of active regions 102, and each column of active regions 102 is displaced in a direction D1 relative to two adjacent columns of active regions 102.

In addition to the access transistor 100, a bit line BL and a bit line contact structure 104 are formed on the semiconductor substrate in the intermediate stage shown in FIG. 1A. One of the drain/source electrodes of each access transistor 100 is connected to a bit line BL through a bit line contact structure 104. The extending direction of the bit line BL may be perpendicular to the extending direction of the word line WL. In the example where the word lines WL extend along the direction D1, the bit lines BL may extend along the direction D2. In the embodiment where each active region 102 is shared by two access transistors 100, the bit line BL may be connected to the portion of the active region 102 that serves as a common drain/source through the bit line contact structure 104.

In addition to being connected to the bit line BL through one of the drain/source electrodes, each access transistor 100 is further connected to a storage capacitor to be subsequently formed through another one of the drain/source electrodes. In the embodiment where each active region 102 intersects two word lines WL and is shared by two access transistors 100, each active region 102 has an intermediate portion located between two intersected word lines WL as a common drain/source of two access transistors 100 and is connected to a bit line BL, and the end portions on the two sides are connected to storage capacitors to be subsequently formed. As shown in FIG. 1A, the end portions of the active region 102 are each located between two word lines WL.

Next, according to some embodiments, an insulating structure is formed between the word lines WL, which defines a capacitor contact structure for connecting the end portion of the active region 102 to the storage capacitor.

Referring to FIG. 1B, an insulating structure 106 is formed between word lines WL and is configured to define the location of a capacitor contact structure to be formed subsequently. In some embodiments, the location of the capacitor contact structure is defined by a self-aligned double patterning (SADP) technique. In these embodiments, after the insulating structure 106 is formed, a filling material is formed around the insulating structure 106, and then the insulating structure 106 is removed to expose the opening defined by the insulating structure 106. The opening is configured to accommodate the capacitor contact structure.

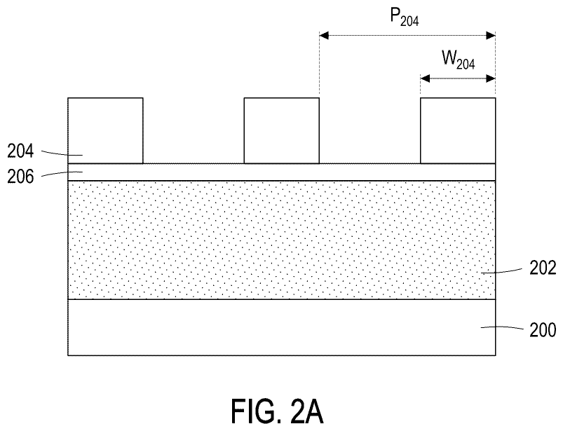

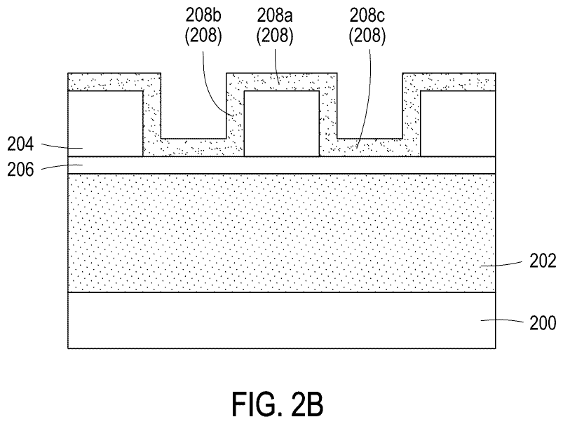

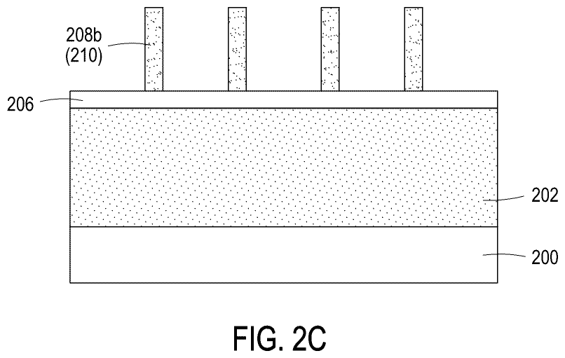

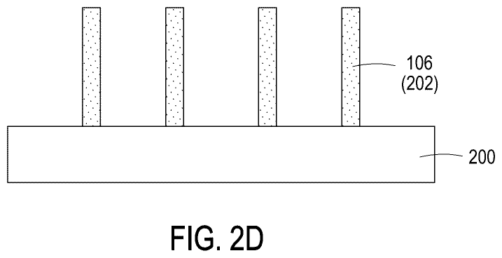

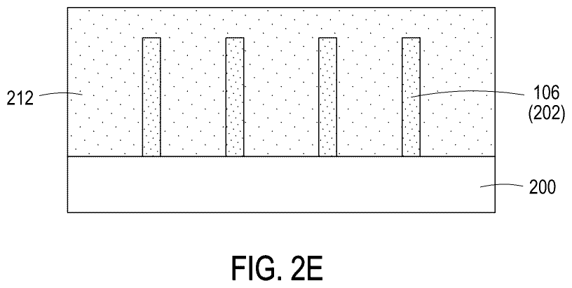

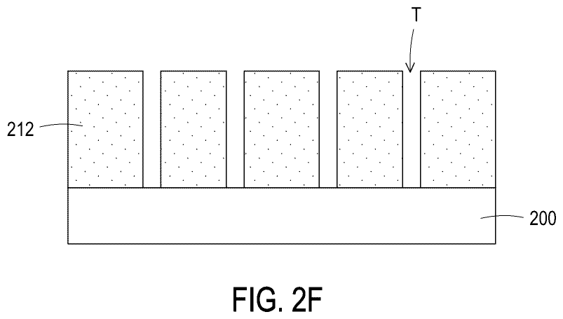

Referring to FIG. 2A, a first insulating material layer 202 is first formed on a substrate structure 200, and a core pattern 204 is formed on the first insulating material layer 202. Although not specifically shown, the substrate structure 200 at least includes the structure shown in FIG. 1A. The first insulating material layer 202 fully covers the substrate structure 200, and will be patterned into the insulating structure 106 shown in FIG. 1B in a subsequent step. The core pattern 204 is configured to form an etching mask for patterning the first insulating material layer 202. In some embodiments, a liner layer 206 is pre-formed on the first insulating material layer 202 before forming the core pattern 204.

In the step shown in FIG. 2B, a shell layer 208 is formed to conformally cover the structure shown in FIG. 2A. Specifically, the first lateral extending portion 208a of the shell layer 208 covers the top surface of the core pattern 204, and the longitudinal extending portion 208b of the shell layer 208 covers the sidewall of the core pattern 204. In addition, the second lateral extending portion 208c of the shell layer 208 extends laterally between the core patterns 204.

In the step shown in FIG. 2C, an anisotropic etching process is performed to remove the first lateral extending portion 208a and the second lateral extending portion 208c of the shell layer 208 and to remove the core pattern 204. As a result, the longitudinal extending portions 208b of the shell layer 208 originally on the two sides of each core pattern 204 are left, which are also referred to as masks 210. As a result, each core pattern 204 is converted into two masks 210, and the pattern pitch is halved.

In the step shown in FIG. 2D, the portion of the first insulating material layer 202 not shielded by the mask 210 is removed by an etching process, and then the mask 210 is removed. As a result, the remaining portion of the first insulating material layer 202 forms the insulating structure 106 described with reference to FIG. 1B.

In the step shown in FIG. 2E, a second insulating material layer 212 is fully formed. The second insulating material layer 212 fills up the space around the insulating structure 106, and may be formed to a height higher than the top of the insulating structure 106. Furthermore, the material of the second insulating material layer 212 is selected to have a sufficient etching selectivity with respect to the insulating structure 106. As an example, when the material of the insulating structure 106 (i.e., the material of the first insulating material layer 202) is silicon oxide, the material of the second insulating material layer 212 may be silicon nitride.

In the step shown in FIG. 2F, the second insulating material layer 212 is planarized until the insulating structure 106 is exposed. Subsequently, the insulating structure 106 is removed, and an opening T is formed in the second insulating material layer 212. In subsequent steps, a capacitor contact structure (not shown) is formed in the opening T.

It may be seen from the above method that the core pattern 204 is used to define the masks 210 with double the amount and half the pitch, and the masks 210 are used to define the outline of the insulating structure 106. In addition, by removing the insulating structure 106, an opening T is defined in the second insulating material layer 212, which determines the location of the capacitor contact structure. Therefore, the pattern of the capacitor contact structure is defined by the insulating structure 106, and the pattern of the insulating structure 106 is affected by the core pattern 204.

As a result of continuous miniaturization, the spacing between the insulating structure 106 and the word line WL becomes very short (as shown in FIG. 1B). In certain cases, the insulating structure 106 even overlaps the word line WL. This may result in the capacitor contact structure not being properly spaced apart from the word line WL, which may cause leakage or increased parasitic capacitance between the two.

To verify the above problem, in addition to forming the structure shown in FIG. 1B in the chip region of the semiconductor substrate, a test structure is further formed in the scribe line region of the semiconductor substrate. The test structure in the scribe line region is the same as the array structure in the chip region, but the test structure includes fewer repeating units and is different in the design of the insulating structure. By observing the relative position relationship between the insulating structure 106 and the word line WL in the test structure, the relative position relationship between the insulating structure 106 and the word line WL in the chip region may be accurately known.

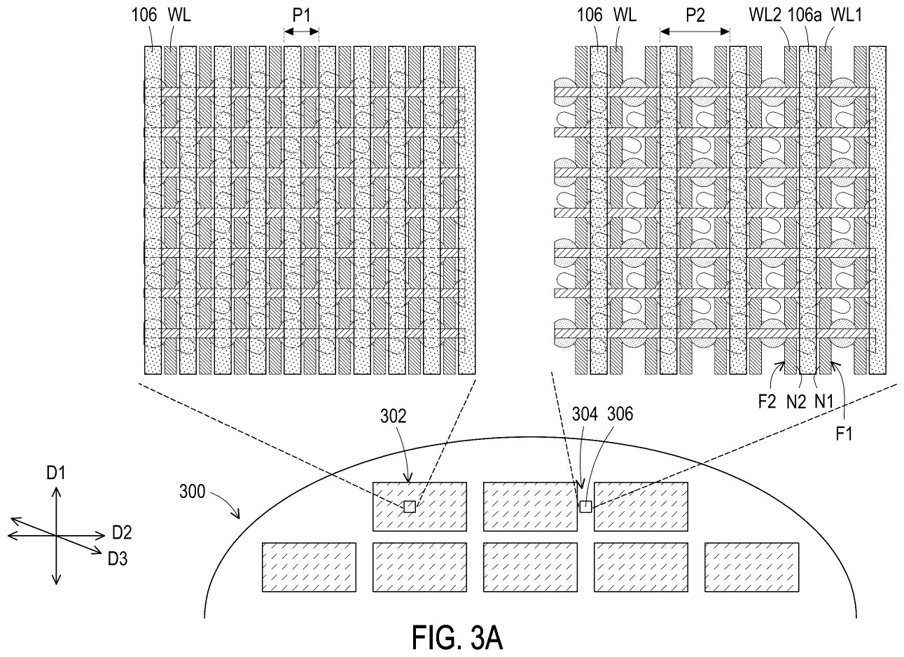

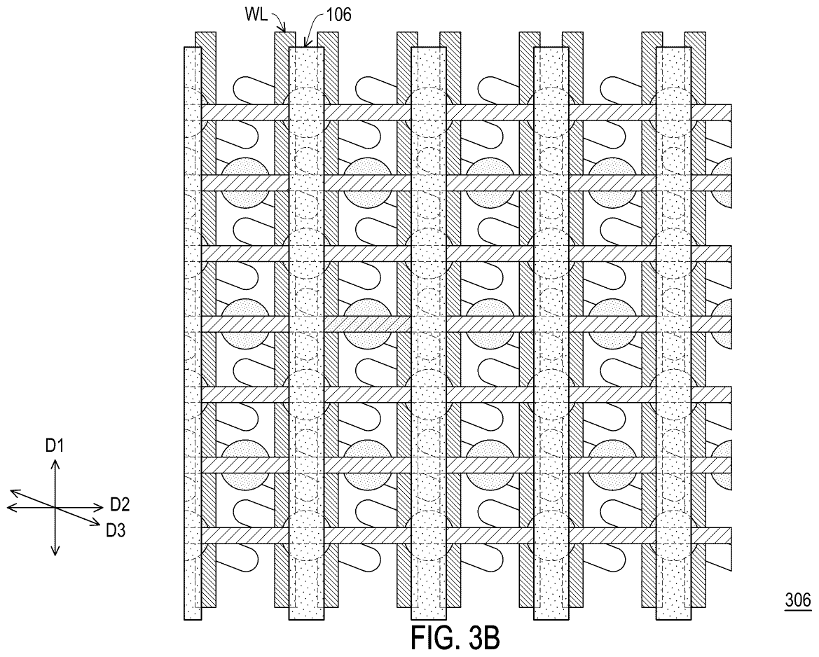

As shown in FIG. 3A, a semiconductor wafer 300 includes chip regions 302 arranged in an array, and scribe line regions 304 extending between the chip regions 302. As shown in FIG. 1B, the array structure is disposed in the chip region 302, and the test structure 306 is disposed in the scribe line region 304. The test structure 306 is similar to the array structure in the chip region 302, and also includes components such as the active region 102, the word line WL, the bit line contact structure 104, the bit line BL, and the insulating structure 106. However, compared to the array structure in the chip region 302, the test structure 306 includes fewer repeating units and differs in the pitch of the insulating structure 106.

Specifically, the insulating structures 106 in the chip region 302 have a pitch P1, and the insulating structures 106 in the test structures 306 in the scribe line region 304 have a pitch P2 that is greater than the pitch P1. In some embodiments, the pitch P2 is approximately twice the pitch P1. In these embodiments, the insulating structures 106 and the word lines WL in the chip region 302 are arranged alternately, and the insulating structures 106 in the test structures 306 in the scribe line region 304 are disposed between the word lines WL at intervals. Specifically, in the test structure 306 in the scribe line region 304, an insulating structure 106 is placed every two word lines WL in the direction D2. This allows two word lines WL to be placed between adjacent insulating structures 106 within the test structure 306. In comparison, an insulating structure 106 is placed every other word line WL in the chip region 302, so that there is only a single word line WL between adjacent insulating structures 106.

Based on the fact that the insulating structures 106 in the test structure 306 in the scribe line region 304 are disposed between the word lines WL at intervals, even when the spacing between the insulating structure 106 and the adjacent word line WL is considerably short or even when the two partially overlap, at least a partial outline of the word line WL may still be observed. In this way, it is still possible to verify whether the appropriate distance is maintained between insulating structure 106 and the word line WL through the outline of each insulating structure 106 and a portion of the outlines of the adjacent word lines WL. For example, when the two opposite sides of the insulating structure 106a are close to the near edges N1 and N2 of the word lines WL1 and WL2, it is difficult to observe the spacing between the opposite sides of the insulating structure 106a and the near edges N1 and N2 of the word lines WL1 and WL2. Even so, the relative position relationship between the insulating structure 106a and the word lines WL1/WL2 may still be identified by the relationship between the opposite sides of the insulating structure 106a and the far edges F1 and F2 of the word lines WL1 and WL2, because no insulating structure 106 is disposed at the far edges F1 and F2 of the word lines WL1 and WL2. Accordingly, the relative position relationship between the insulating structure 106 and the word line WL in the chip region 302 may be accurately identified by observing the insulating structure 106 and the word line WL in the test structure 306.

In an embodiment using a self-aligned double patterning technique (described with reference to FIG. 2A to FIG. 2F) to define the insulating structure 106, the design shown in FIG. 3A may be realized by implementing different widths and pitches for the core pattern 204 in the chip region 302 and the core pattern 204 in the test structure 306 in the scribe line region 304. Specifically, in these embodiments, the width W₂₀₄ of the core pattern 204 in the test structure 306 is approximately twice the width W₂₀₄ of the core pattern 204 in the chip region 302, and the pitch P₂₀₄ of the core pattern 204 in the test structure 306 is approximately twice the pitch P₂₀₄ of the core pattern 204 in the chip region 302.

In an embodiment using a self-aligned double patterning technique to define both the word line WL and the insulating structure 106, the center line of the core pattern 204 for defining the insulating structure 106 in the test structure 306 is substantially aligned with the center line of the core pattern (not shown) for defining the word line WL. In comparison, the center line of the core pattern 204 configured to define the insulating structure 106 in the chip region 302 is offset relative to the center line of the core pattern (not shown) configured to define the word line WL.

Referring to FIG. 3B, when the word line WL undergoes pitch walking, the pitch size of the word line WL alternates. As a result, the word lines WL on the two sides of each insulating structure 106 may move toward the insulating structure 106 therebetween and partially overlap the insulating structure 106 therebetween. Even so, at least another side of each word line WL does not overlap any insulating structure 106. This means that the relative position relationship between the insulating structure 106 and the word line WL in the chip region 302 may be verified by observing the relationship between the outline of each insulating structure 106 in the test structure 306 and the outline of the unshielded side of the adjacent word line WL. Since the pitch of the insulating structure 106 in the test structure 306 is increased, even if a serious word line WL pitch walking occurs, the word line WL may be prevented from being completely shielded, and the exposed portion of the word line WL may be used for pattern verification.

In the embodiments described above, a self-aligned double patterning technique is used to define the capacitor contact structure. In other embodiments, a self-aligned reverse patterning technique is used to define the capacitor contact structure.

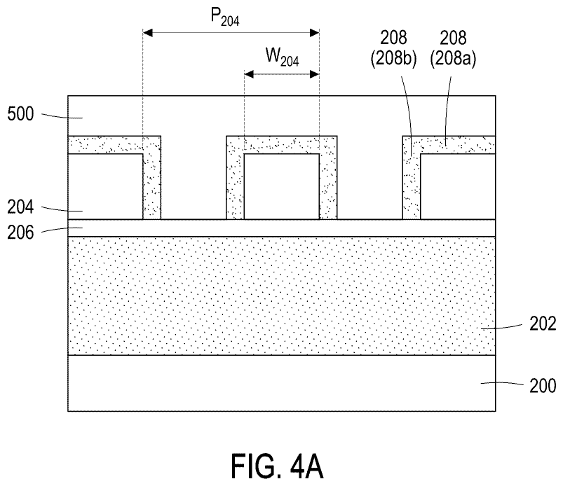

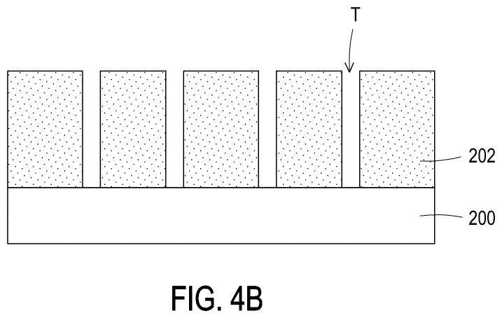

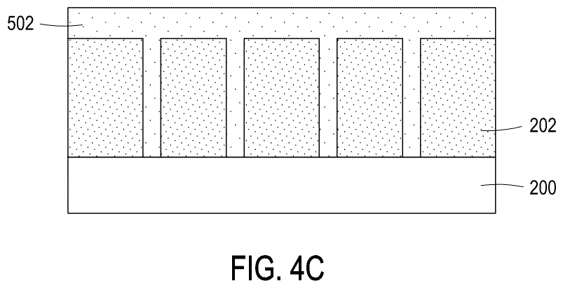

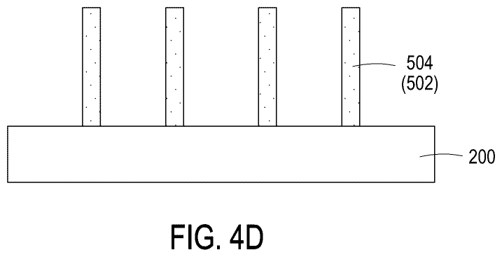

The self-aligned reverse patterning process is similar to the self-aligned double patterning process in its initial stages, and also includes the steps described with reference to FIG. 2A and FIG. 2B. After the shell layer 208 is formed, as shown in FIG. 4A, the second lateral extending portion 208c of the shell layer 208 is removed, while the first lateral extending portion 208a and the longitudinal extending portion 208b are retained, and a dielectric layer 500 is formed to fully cover the obtained structure. In some embodiments, before forming the dielectric layer 500, the first lateral extending portion 208a of the shell layer 208 may be removed, leaving only the longitudinal extending portion 208b of the shell layer 208. In order to selectively remove the remaining portion of the shell layer 208 in a subsequent step, the material of the shell layer 208 should have a sufficient etching selectivity relative to the materials of the dielectric layer 500 and the core pattern 204.

At the stage shown in FIG. 4B, the top portion of the dielectric layer 500 is first removed to expose the remaining portion of the shell layer 208, and then the remaining portion of the shell layer 208 is selectively remove to leave only the core pattern 204 and the remaining portion of the dielectric layer 500. Next, an etching operation is performed using the core pattern 204 and the remaining portion of the dielectric layer 500 as a mask. As a result, the portion of the first insulating material layer 202 (and the liner layer 206) not masked by the mask is removed, and an opening T is formed in the first insulating material layer 202.

At the stage shown in FIG. 4C, a second insulating material layer 502 is formed on the current structure. Specifically, the second insulating material layer 502 fills up the opening T in the first insulating material layer 202 and further extends onto the top surface of the first insulating material layer 202. In order to selectively remove the first insulating material layer 202 in a subsequent step, the material of the second insulating material layer 502 has a sufficient etching selectivity relative to the material of the first insulating material layer 202.

At the stage shown in FIG. 4D, the top portion of the second insulating material layer 502 may be removed until the first insulating material layer 202 is exposed. As a result, a portion of the second insulating material layer 502 filling the opening T in the first insulating material layer 202 remains. Next, the first insulating material layer 202 may be selectively removed, leaving a remaining portion of the second insulating material layer 502, which is also referred to as an insulating structure 504.

Subsequently, a capacitor contact structure (not shown) is formed between the insulating structures 504. It may be seen from the above method that the core pattern 204 is used to define the longitudinal extending portion 208b of the shell layer 208, which further defines the opening T in the first insulating material layer 202. The opening T determines the location of the insulating structure 504, and the gap between the insulating structures 504 determines the location of the capacitor contact structure.

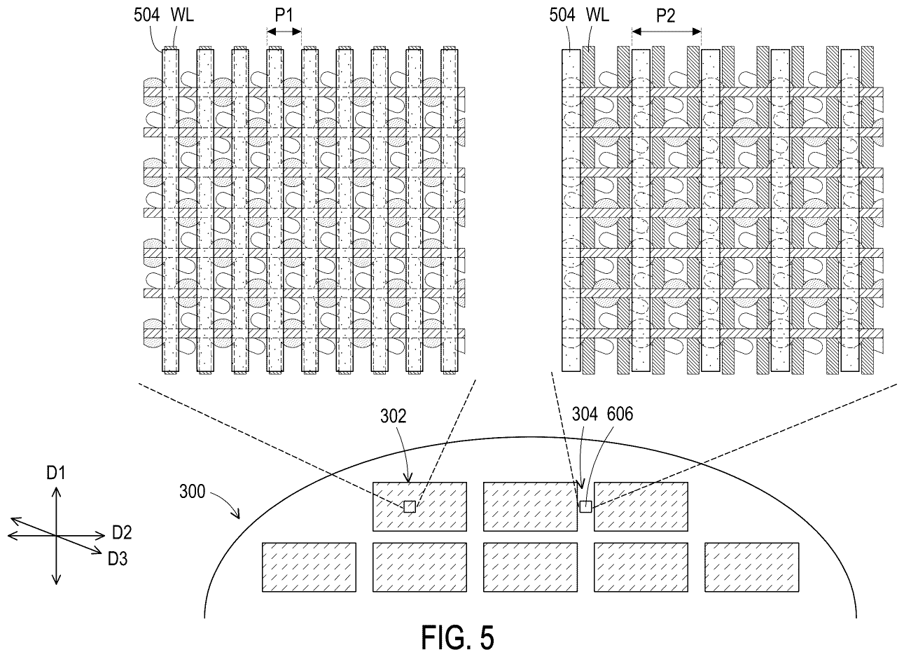

The embodiment of FIG. 5 is similar to the embodiment of FIG. 3A, but in the embodiment shown in FIG. 5, the location of the capacitor contact structure is defined by the gap between the insulating structures 504. As shown in FIG. 5, in the chip region 302, the insulating structures 504 overlap the word lines WL and are periodically arranged with a pitch P1. On the other hand, the insulating structures 504 in the test structures 606 of the scribe line region 304 are located between adjacent word lines WL and are periodically arranged with a pitch P2 greater than the pitch P1. In some embodiments, the pitch P2 is approximately twice the pitch P1. In these embodiments, the insulating structures 504 in the test structure 606 are disposed between the word lines WL at intervals. In addition, an insulating structure 504 is disposed on one side of each word line WL in the test structure 606, while no insulating structure 504 is disposed on the other side, so at least one side is not shielded by any insulating structure 504.

In an embodiment using a self-aligned reverse patterning technique (described with reference to FIG. 4A to FIG. 4D) to define the insulating structure 504, the design shown in FIG. 5 may be realized by implementing different widths and pitches for the core pattern 204 in the chip region 302 and the core pattern 204 in the test structure 606 in the scribe line region 304. Specifically, in these embodiments, the width W₂₀₄ of the core pattern 204 in the test structure 606 is approximately twice the width W₂₀₄ of the core pattern 204 in the chip region 302, and the pitch P₂₀₄ of the core pattern 204 in the test structure 306 is approximately twice the pitch P₂₀₄ of the core pattern 204 in the chip region 302.

In an embodiment using a self-aligned double patterning technique to define both the word line WL and the insulating structure 504, the center line of the core pattern 204 for defining the insulating structure 504 in the test structure 606 is substantially aligned with the center line of the core pattern (not shown) for defining the word line WL. On the other hand, the center line of the core pattern 204 for defining the insulating structure 504 in the chip region 302 is also substantially aligned with the center line of the core pattern (not shown) for defining the word line WL.

In summary, the disclosure provides a memory integrated circuit and a manufacturing method thereof. The memory integrated circuit includes a memory array formed in a chip region of a semiconductor wafer and includes a test structure formed in a scribe line region of the semiconductor wafer. The test structure is similar to the memory array in the chip region and is configured to verify the pattern configuration of the memory array in the chip region. The memory array in the chip region and the test structure in the scribe line region both include multiple word lines and multiple insulating structures for defining capacitor contact structures. The word line and the insulating structure extend in the same direction. In the chip region, word lines and insulating structures are arranged alternately. On the other hand, in the test structure in the scribe line region, the insulating structures are disposed between the word lines at intervals. This ensures that at least one side of each word line in the test structure is free of any insulating structure. Even if the insulating structure is quite close to or partially overlaps the word line, at least one side of each word line is not shielded by any insulating structure. In this way, the relative position relationship between the insulating structure and the word line in the test structure may still be observed, and may be configured to know the relative position relationship between the word line and the insulating structure in the chip region. Accordingly, the relative position relationship between the word line and the capacitor contact structure in the chip region may be accurately verified. As another option, within the test structure in the scribe line region, the insulating structure overlaps the word line at intervals. This ensures that the word lines on the two sides of the insulating structure are not shielded, and may be configured to identify the relative position relationship between the word lines and the insulating structure.

As described above, the lithography verification mechanism provided by the embodiments of the disclosure may also be applied to manufacturing other memory integrated circuits or any integrated circuits with a periodic pattern. Specifically, the array structure in the chip region may be replaced with other functional pattern arrays different from the DRAM array, and the test structure is correspondingly formed in the scribe line according to the method described herein. As an example, the functional pattern array and the test structure respectively include multiple first patterns similar to word lines and multiple second patterns similar to the above-mentioned insulating structure. The second pattern is configured to define a location of a third pattern similar to a capacitor contact structure. In addition, the second patterns in the functional pattern array are arranged at a first pitch, and the second patterns in the test structure are arranged at a second pitch greater than the first pitch. In some embodiments, a second pattern is placed every two first patterns in each test structure. In some embodiments, the first pattern and the second pattern are arranged alternately in each functional pattern array. In some embodiments, at least one side of each first pattern in each test structure is not adjacent to or overlapped with any second pattern. In some embodiments, in each functional pattern array, a first pattern overlaps with a second pattern.

What is claimed is:

1. A memory integrated circuit, comprising:
a plurality of memory arrays located in a plurality of chip regions of a semiconductor wafer; and
a plurality of test structures located in a scribe line region of the semiconductor wafer,
wherein the memory arrays and the test structures respectively comprise a plurality of word lines and a plurality of insulating structures extending along a same direction, the insulating structures in each of the memory arrays are configured to define a plurality of capacitor contact structures, the insulating structures in each of the memory arrays are arranged with a first pitch, and the insulating structures in each of the test structures are arranged with a second pitch greater than the first pitch.

2. The memory integrated circuit according to claim 1, wherein one of the insulating structures is placed every two of the word lines in each of the test structures.

3. The memory integrated circuit according to claim 1, wherein the word lines and the insulating structures are arranged alternately in each of the memory arrays.

4. The memory integrated circuit according to claim 2, wherein at least one side of each of the word lines is not adjacent to any one of the insulating structures in each of the test structures.

5. The memory integrated circuit according to claim 2, wherein the word lines respectively overlap one of the insulating structures in each of the memory arrays.

6. The memory integrated circuit according to claim 1, wherein the second pitch is approximately twice the first pitch.

7. The memory integrated circuit according to claim 1, wherein locations of the insulating structures define locations of the capacitor contact structures in each of the memory arrays.

8. The memory integrated circuit according to claim 1, wherein gaps between the insulating structures define locations of the capacitor contact structures in each of the memory arrays.

9. A memory integrated circuit, comprising:
a plurality of functional pattern arrays located in a plurality of chip regions of a semiconductor wafer; and
a plurality of test structures located in a scribe line region of the semiconductor wafer,
wherein the functional pattern arrays and the test structures respectively comprise a plurality of first patterns and a plurality of second patterns extending along a same direction, the second patterns in each of the functional pattern arrays are configured to define locations of a plurality of third patterns, the second patterns in each of the functional pattern arrays are arranged with a first pitch, and the second patterns in each of the test structures are arranged with a second pitch greater than the first pitch.

10. The memory integrated circuit according to claim 9, wherein one of the second patterns is placed every two of the first patterns in each of the test structures.

11. The memory integrated circuit according to claim 9, wherein the first patterns and the second patterns are arranged alternately in each of the functional pattern arrays.

12. The memory integrated circuit according to claim 10, wherein at least one side of each of the first patterns is not adjacent to any one of the second patterns in each of the test structures.

13. The memory integrated circuit according to claim 10, wherein the first patterns respectively overlap one of the second patterns in each of the functional pattern arrays.

14. A manufacturing method of a memory integrated circuit, comprising:
forming a plurality of memory arrays in a plurality of chip regions of a semiconductor wafer; and
forming a plurality of test structures in a scribe line region of the semiconductor wafer,
wherein the memory arrays and the test structures respectively comprise a plurality of word lines and a plurality of insulating structures extending along a same direction, the insulating structures in each of the memory arrays are configured to define a plurality of capacitor contact structures, the insulating structures in each of the memory arrays are arranged with a first pitch, and the insulating structures in each of the test structures are arranged with a second pitch greater than the first pitch.

15. The manufacturing method of the memory integrated circuit according to claim 14, wherein the insulating structures are replaced with the capacitor contact structures in each of the memory arrays.

16. The manufacturing method of the memory integrated circuit according to claim 14, wherein the capacitor contact structures are formed in gaps between the insulating structures in each of the memory arrays.

17. The manufacturing method of the memory integrated circuit according to claim 14, wherein forming the insulating structures in each of the memory arrays or each of the test structures comprises:
forming a first insulating material layer on a substrate structure;
forming a plurality of core patterns on the first insulating material layer;
forming a shell layer conformally covering the core patterns and the first insulating material layer;
removing a lateral extending portion of the shell layer while retaining a longitudinal extending portion of the shell layer covering sidewalls of the core patterns;
removing the core patterns;
etching the first insulating material layer using the longitudinal extending portion of the shell layer as a mask to pattern the first insulating material layer into the insulating structures; and
removing the longitudinal extending portion of the shell layer.

18. The manufacturing method of the memory integrated circuit according to claim 17, wherein a width of each of the core patterns in each of the test structures is approximately twice a width of each of the core patterns in each of the memory arrays, and a pitch of the core patterns in each of the test structures is approximately twice a pitch of the core patterns in each of the memory arrays.

19. The manufacturing method of the memory integrated circuit according to claim 14, wherein forming the insulating structures in each of the memory arrays or each of the test structures comprises:
forming an insulating material layer on a substrate structure;
forming a plurality of core patterns on the insulating material layer;
forming a shell layer conformally covering the core patterns;
forming a dielectric layer that fully covers the shell layer and the insulating material layer;
removing the shell layer;
etching the insulating material layer using the core patterns and the dielectric layer as a mask to form a plurality of openings in the insulating material layer; and
filling the insulating structures into the openings.

20. The manufacturing method of the memory integrated circuit according to claim 19, wherein a width of each of the core patterns in each of the test structures is approximately twice a width of each of the core patterns in each of the memory arrays, and a pitch of the core patterns in each of the test structures is approximately twice a pitch of the core patterns in each of the memory arrays.
